(19) United States
(12) Patent Application Publication
(10) Pub. No.: US 2006/0007861 A1
(43) Pub. Date: Jan. 12, 2006

(54) Mechanism to support high speed circuit switched data services via an iu interface

(75) Inventors: Bernd Kurzmann, Wien (AT); Alexander Vesely, Wien (AT)

Correspondence Address: MORRISON & FOERSTER LLP, 1650 TYSONS BOULEVARD, SUITE 300, MCLEAN, VA, 22102, US

(73) Assignee: Siemens Aktiengesellschaft, Muchen (DE)

(21) Appl. No.: 10/510,825

(22) PCT Filed: Apr. 12, 2002
(86) PCT No.: PCT/EP02/04112

§ 371 Date: Aug. 19, 2005

(51) Int. Cl. G01R 31/08

(52) U.S. Cl. 370/235; 370/348

(57) ABSTRACT

Method for initiating a HSCSD call set-up in a cellular mobile telecommunication system, wherein a RAB Assignment message is sent between a switching device (3G-MSC or MGW) to a base station controller (GERAN-BSC), containing the description of allowed multislot configurations for the HSCSD call which is to be initiated.

The invention concerns methods and devices for initiating a HSCSD call set-up in a cellular mobile telecommunication system.

Several circuit switched (CS) data services are defined for PLMN networks. The delivery of CS data services via the Iu interface for mobile access in UTRAN and via the A interface for mobile access in GSM/GERAN A/Gb mode are defined and standardised (www.etsi.org, www.3gpp.org). To achieve higher data rates on the air interface, the feature High Speed Circuit Switched Data (HSCSD) was defined and standardised for GSM/GERAN A/Gb mode, which is not applicable for UTRAN, where the radio link can provide higher data rates without the HSCSD feature, i.e. HSCSD is not defined/standardised for the access via the Iu interface.

An object of the invention is to efficiently allow using HSCD for GERAN Iu mode. This object is achieved by the invention set out in the independent claims.

The problem of using HSCD for the Iu interface is not solved so far as HSCSD via the Iu interface is not applicable to UTRAN. With this invention HSCSD services can be delivered in GERAN Iu mode. HSCSD via Iu interface will be a new feature for GERAN Iu mode. Impacts on MSC-S/MGW/IWF/BSC and mobile equipment are reduced to a minimum. Reuse of existing functionality provided by an IWP is possible. Signalling between BSC and MGW/IWF is faster using inband signalling (user plane) instead of outband signalling (control plane). No GERA.N specific elementary procedure is required to be included into the RANAP, which was designed for UTRAN

An advantage of the invention is that it allows to reuse existing mechanisms of the Iu interface, which were designed and are used for speech services, separation of user plane and control plane is achieved, i.e. signalling changes of multi-slot configuration, i.e. changes of the datarate is performed in the user plane and not via control plane. In GSM the out of band solution for indicating the new HSCSD configuration to the MSC/MGW caused delay, which is avoided using the new in-band solution.

Further advantages of the invention will be more apparent from the following detailed explanation of the invention in connection with the accompanying drawings, wherein

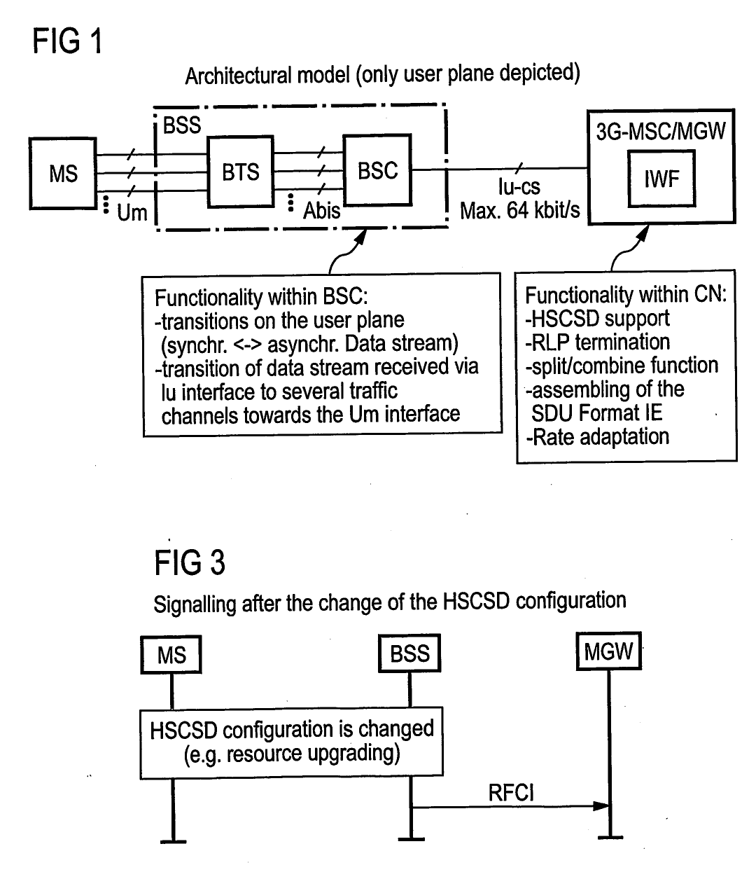

FIG. 1 is a schematic of the architectural model of a telecommunication network (only user plane depicted),

FIG. 2 shows a call set-up for mobile originated call establishment and

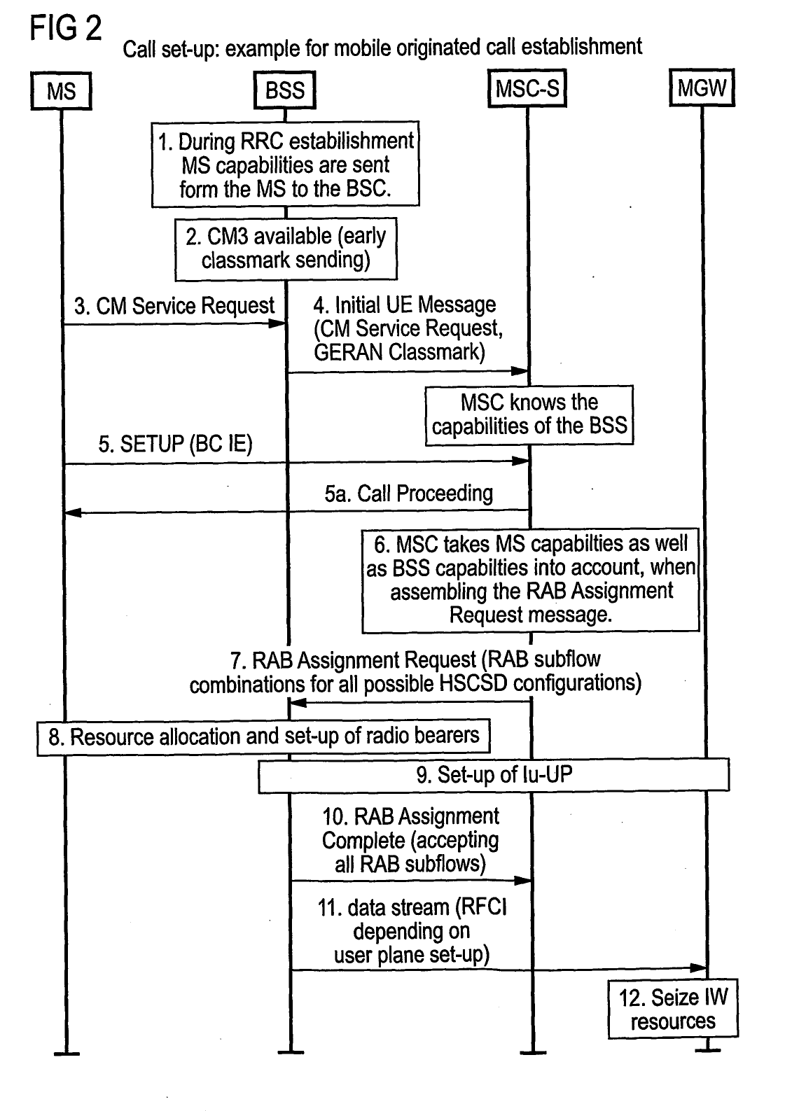

FIG. 3 shows signalling after the change of the HSCSD configuration.

The example in the drawings describes how CS data services using HSCSD can be delivered via the Iu interface in GERAN Iu mode.

A HSCSD connection is to be set up between a switching device (MSC/MGW) and a mobile station (MS) where the MS communicates over the air interface with a BTS (controlled by a BSC via an Abis- interface) of the base station subsystem BSS of a cellular mobile telecommunication network.

Within FIG. 1 the architectural model for the connection of GERAN in Iu mode (via the Iu interface) towards the CN is depicted.

Description of Functionalities:

By a base station controller BSC,
depending on the transport layer (STM versus ATM) a transition of asynchronous data stream (via Iu interface) to synchronous data stream and vice versa (required for CS speech services as well) is executed and
a transition of a data stream received via Iu interface into several traffic channels towards the Um interface (Abis) and vice versa (only required in a HSCSD configuration) is performed.
   Functions of an InterworkingFunction IWF are:
HSCSD support (only required in a HSCSD configuration, as currently used for GSM/GERAN A/Gb mode) is provided,
RLP termination (protocol between MS and CN, as currently used for non-transparent CS data services)
split/combine function (as currently used for GSM/GERAN A/Gb mode)
assembling of the SDU Format IE (according to the proposed solution, see below)
rate adaptation (as currently used for GSM/GERAN A/Gb mode)

As the functions provided by the IWP are corresponding to the currently used HSCSD configuration on the radio link, it has to be aware of the currently used HSCSD configuration, i.e. during call establishment, change of HSCSD configuration, during Handover/Relocation.

HSCSD via Iu Interface:

During call set-up the MSC-S assembles the RANAP RAB Assignment Request message taking into account its own capabilities as well as the capabilities of the MS, BSC, IWF. Within this message an Information Element is included (SDU Format IE describing requested RAB subflow combinations), which is suitable to describe all allowed multislot configurations (also termed HSCSD configuration within the text) on the radio interface for a certain call. The multislot configuration can be described by signalling means that are usually used for CS speech services in case of UTRAN access.

Therefore, for HSCSD via the Iu interface, the MSC-S shall assemble the SDU Format IE describing all allowed HSCSD configurations, allowed for the call, unless the allowed set of HSCSD configurations needs to be modified. (Changes in the set of allowed HSCSD configurations is possible during the Relocation procedure.). The multislot configuration will be described in the SDU Format IE in the way that one RAB Subflow corresponds to one slot. Multislot configurations with n slots will then be described as RABs having n subflows. The subflows are described using the Subflow SDU Size IE within the SDU Format Information Parameter IE.
The BSC will, after reception of the RANAP RAB Assignment Request message, initialize the user plane according to the information received in the SDU Format IE. Towards the MGW the Iu UP protocol will be used. During the UP initialization procedure the BSC is able to indicate the HSCSD configuration, which willinitially be used for the data transfer, by indicating the corresponding RAB subflow combination as the first element in the list of RAB subflows to be initialised. RFCI values, corresponding to the different RAB subflows, will be negotiated between BSC and MGW.
Due to the first element in the list of RAB subflows the MGW is aware of which RAB subflow, which is corresponding to a certain HSCSD configuration, the BSC intends to use after the set-up procedure is successfully executed. The MGW can inform the IWF, which can be seized according to the selected HSCSD configuration.
Data transmission on the user plane starts as described above.
If during the call the BSC decides to change the HSCSD configuration (possibly after a BSC-internal handover, which is not visible to the CN), the BSC can indicate this new HSCSD configuration to the MGW in-band within the Iu UP frame with the appropriate RFCI value, which corresponds to the new HSCSD configuration on the radio link and was negotiated during the initialisation of the user plane. The MGW passes the information to the IWF. The IWF is seized according to the new HSCSD configuration.
During Relocation (i.e. handover with CN involvement), a new Iu interface leg towards the target BSC will be set-up. During the establishment of the new Iu interface leg, the user plane of this Iu interface leg will be initialised as well. With respect to the exchange of SDU Format information out of band and the corresponding UP initialisation, the same mechanisms as for the call establishment (see description above) apply for the Relocation procedure as well. In case the capabilities of the target BSC/GERAN are different the set of RAB subflow combinations may be different from that of the source BSC.

A description of call flows (examples), where the invention has to be applied follows with reference to FIG. 2:

Call Set-Up:

The call set-up has to be performed as described in FIG. 2. The call flow in FIG. 2 follows the existing procedures with some modifications described in the following text:
1. MS capabilities required for CS data services, which are not contained in CM3, are sent to the BSS during RRC establishment, i.e. Full rate/Half rate support, Allowed Channel codings and Assymetry Indication (covered by working assumption of GERAN WG2).
2. The MS informs the BSS about its multislot capabilities by using the early classmark sending.
3. The MS sends the CM service Request message to the BSC.
4. The BSC forwards the CM Service Request inside the Initial UE Message to the CN. Within this message the BSC includes the GERAN Classmark to inform the MSC about the BSS capabilities. With this information the possible HSCSD configuration can be restricted to those which are supported by all affected entities (MS, GERAN, CN).
5. With the SETUP message the BC IE is sent to the MSC. The MSC answers with the Call Proceeding message, indicating the accepted FNUR to the MS.
6. The MSC possibly restricts the requested air interface user rate, taking into account the capabilities of the IWF, BSS and the MS. The MSC assembles a RAB Assignment Request message containing the description of the RAB subflow combinations for all allowed HSCSD configurations.
7. The MSC sends the RAB Assignment Request message to the BSC.
8. The BSS allocates resources and performs the set-up of appropriate channels.
9. The BSS initiates the set-up of the Iu-Up towards the MGW.
10. If the set-up of the Iu-UP was successful, the BSS sends the RAB Assignment Complete message to the MSC.
11. Depending on the user plane set-up (see 25.415), the BSC is under control, which HSCSD configuration to be used initially. Therefore no outband signalling is required to indicate the HSCSD configuration to the IWF.
12. The IWF is seized accordingly.
   Change of HSCSD Configuration:

As depicted in FIG. 3, the new configuration is signalled to the IWF using the appropriate RFCI value, which is sent together with each data packet.

If the MGW receives a data packet with a new RFCI value, it has to inform the IWF. The IWF can be seized according to the new HSCSD configuration.

Abbreviations:

ATM Asynchronous Transmission Mode

BC Bearer Capabilities

BSC Base Station Controller

BSS Base Station System

BTS Base Transceiver Station

CM Classmark, Connection Management

CN Core Network

CS Circuit Switched

GERAN GSM/EDGE Radio Acess Network

HSCSD High Speed Circuit Switched Data

IE Information Element

IWF InterWorking Function

MGW Media Gateway

MS Mobile Station

MSC-S Mobile Switching Centre-Server

PLMN Public Land Mobile Network

RAB Radio Access Bearer

RANAP Radio Access Network Application Part

RFCI RAB subFlow Combination Identifier

RLP Radio Link Protocol

RRC Radio Resource Control

SDU Signalling Data Unit

STM Synchronous Transmission Mode

UP User Plane

UTRAN UMTS Terrestrial Radio Access Network

1. Method for initiating a HSCSD call set-up in a cellular mobile telecommunication system,
wherein a RAB Assignment message is sent between a switching device (3G-MSC or MGW) to a base station controller (GERAN-BSC) containing a description of allowed multislot configurations for the HSCSD call which is to be initiated.

2. Method according to claim 1,
wherein the mobile switching centre (MSC) assembles a RANAP RAB Assignment Request message taking into account its (MSC) own capabilities as well as capabilities of the mobile station (MS) for which the setup is initiated and/or of the base station controller (GERAN-BSC) to which the RAB assignment message is sent, and/or of an interworking function IWF.

3. Method according to claim 1, wherein the HSCSD call set-up enables delivery of a HSCSD service in GERAN Iu mode.

4. Method according to claim 1, wherein within this RAB message an Information Element is included which is suitable to describe all allowed HSCSD multislot configurations using SDU Format IE, which describes the requested RAB subflow combinations.

5. Method according to claim 4, wherein a multislot configuration is transmitted by signaling means that are defined for circuit switched speech services in case of UTRAN access.

6. Method according to claim 1, wherein the HSCSD call is used for circuit switched transmission of other data than speech data.

7. Method according to claim 1, wherein for a change of the current set up HSCSD configuration is signaled to the IWF using the appropriate RFCI value.

8. Device using a method according to claim 1.
